(19) United States
(12) Patent Application Publication
(10) Pub. No.: US 2014/0283909 A1
(43) Pub. Date: Sep. 25, 2014

(54) CONCENTRATING PHOTOVOLTAIC CHIP ASSEMBLY, METHOD FOR MANUFACTURING THE SAME, AND CONCENTRATING PHOTOVOLTAIC ASSEMBLY WITH SAME

(71) Applicant: AMBIT MICROSYSTEMS (ZHONGSHAN) LTD., Zhongshan (CN)

(72) Inventor: FEI REN, Zhongshan (CN)

(73) Assignee: AMBIT MICROSYSTEMS (ZHONGSHAN) LTD., Zhongshan (CN)

(21) Appl. No.: 14/037,388

(22) Filed: Sep. 26, 2013

(30) Foreign Application Priority Data
Mar. 25, 2013 (CN) 2013100976103

(51) Int. Cl. H01L 31/02; H01L 31/048

(52) U.S. Cl. CPC H01L 31/02013; H01L 31/048
USPC 136/259; 438/64

(57) ABSTRACT

A concentrating photovoltaic chip assembly includes an upper lead frame, a lower lead frame for supporting electronic components, a photovoltaic chip for converting solar energy into electric energy, and a protective diode for protecting the photovoltaic chip from short-circuiting. A light inlet window is defined in the upper lead frame. Each of the photovoltaic chip and the protective diode is mounted between the upper lead frame and the lower lead frame and are electrically connect to the upper lead frame and the lower lead frame. The photovoltaic chip faces the light inlet window. A method for manufacturing the concentrating photovoltaic chip assembly is also provided.

### BACKGROUND

1. Technical Field

The present disclosure relates to electronic assemblies and methods for manufacturing the same; and more particularly to a concentrating photovoltaic chip assembly, a method for manufacturing the chip assembly, and a concentrating photovoltaic assembly having the chip assembly.

2. Description of Related Art

Typical solar power systems include a large amount of photovoltaic panels. The most important component of the photovoltaic panel is a photovoltaic chip. The photovoltaic chip is mounted on a substrate to form a solar receiver, which converts solar energy into electric energy. Many solar power systems have the photovoltaic chip mounted on a direct bonded copper (DBC) substrate. In addition, the photovoltaic chip is electrically connected to the DBC by gold wires. The DBC substrate and gold wires are somewhat expensive, and mass production of the solar power system is time consuming. These factors result in high production costs.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is a cross-sectional view of a concentrating photovoltaic assembly in accordance with an exemplary embodiment of the present disclosure, showing essential optical paths thereof.

FIG. 2 is a view of a concentrating photovoltaic chip assembly of the concentrating photovoltaic assembly of FIG. 1.

FIG. 3 is an exploded, perspective view of the concentrating photovoltaic chip assembly of the exemplary embodiment.

FIG. 4 is an assembled view of the concentrating photovoltaic chip assembly of FIG. 3.

FIG. 5 is a flow chart of an exemplary method for manufacturing the concentrating photovoltaic chip assembly of FIG. 4.

### DETAILED DESCRIPTION

The disclosure is illustrated by way of example and not by way of limitation in the figures of the accompanying drawings in which like reference numerals indicate the same or similar elements. It should be noted that references to “an” or “one” embodiment in this disclosure are not necessarily to the same embodiment, and such references can mean “at least one.”

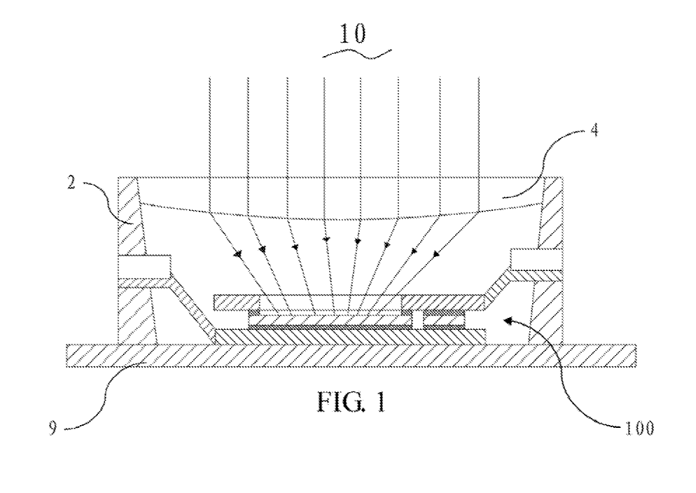

FIG. 1 is a cross-sectional view of a concentrating photovoltaic assembly 10 in accordance with an exemplary embodiment of the present disclosure. The concentrating photovoltaic assembly 10 is mounted on a printed circuit board (PCB) 9. The concentrating photovoltaic assembly 10 comprises a support 2, an optical element 4, and a concentrating photovoltaic chip assembly 100. The optical element 4 is used for concentrating light on a specific area. The optical element 4 is fixed on a top of the support 2. The concentrating photovoltaic chip assembly 100 is fixed to the support 2, with the optical element 4 facing the concentrating photovoltaic chip assembly 100. In the embodiment, the optical element 4 is a convex lens.

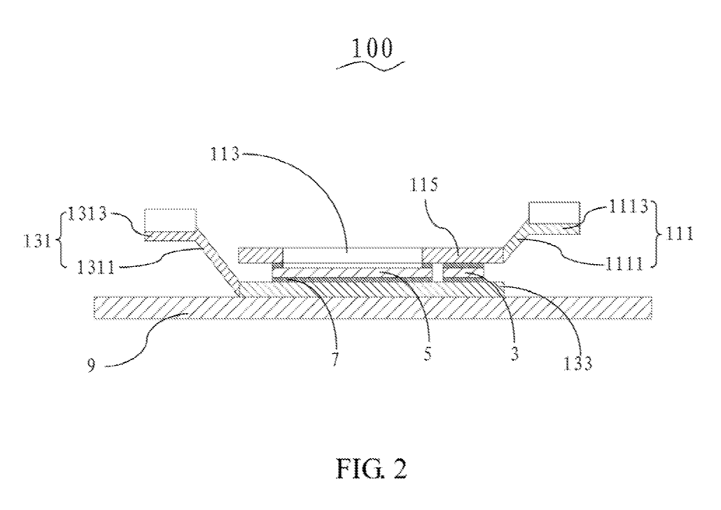

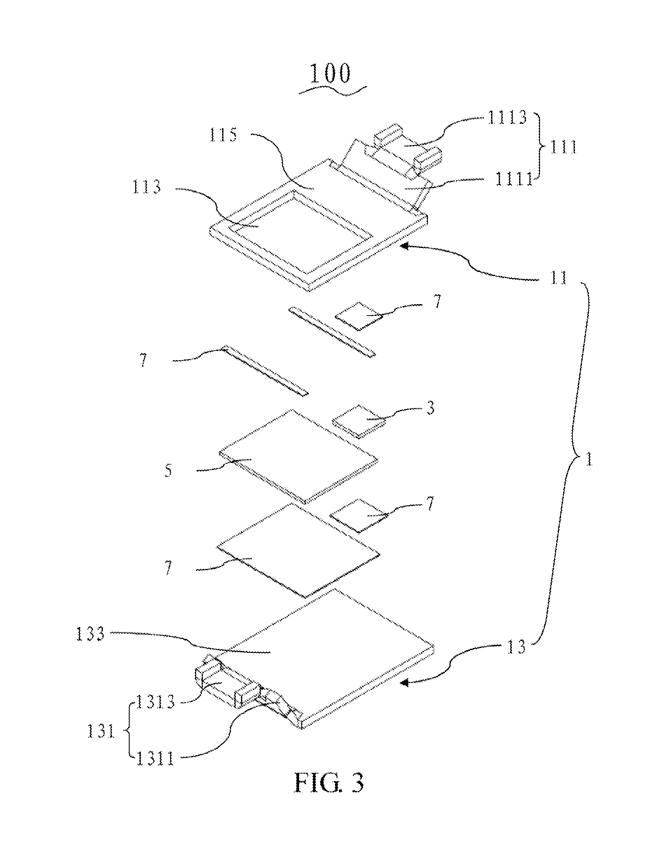

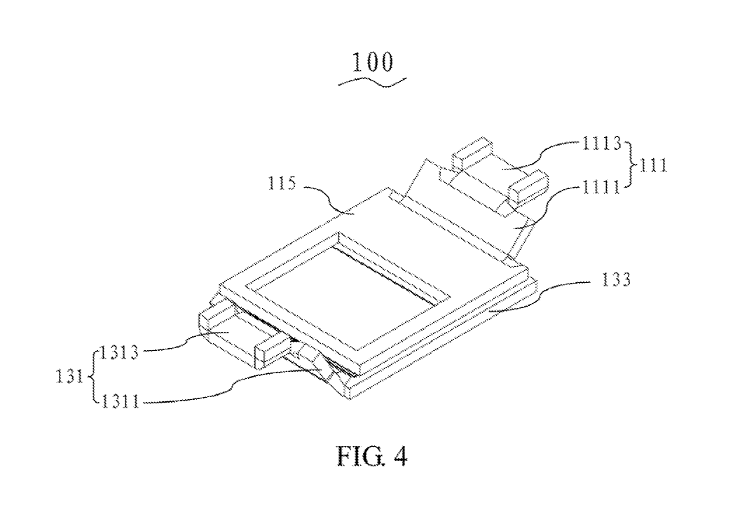

Referring also to FIGS. 2-4, a concentrating photovoltaic chip assembly 100 comprises a lead frame assembly 1 mounted on a printed circuit board (PCB) 9, a photovoltaic chip 5, and a protective diode 3. The lead frame assembly 1 is made of an electrically conductive material. The lead frame assembly 1 comprises an upper lead frame 11 and a lower lead frame 13. The photovoltaic chip 5 and the protective diode 3 are mounted side by side between the upper lead frame 11 and the lower lead frame 13. The photovoltaic chip 5 and the protective diode 3 are connected in series through the upper lead frame 11 and the lower lead frame 13.

The photovoltaic chip 5 is used to convert solar energy into electric energy. In the embodiment, the photovoltaic chip 5 is a solar cell. The protective diode 3 prevents the photovoltaic chip 5 from short-circuiting when a plurality of the concentrating photovoltaic chip assemblies 100 are mounted on the PCB 9 and connected in series. In another embodiment, the photovoltaic chip 5 is a chip comprising a plurality of photovoltaic diodes.

The lower lead frame 13 comprises a lower lead frame body 133 and a lower lead terminal 131. A top surface of the lower lead frame body 133 is used to support and electrically connect to both an electrode of the photovoltaic chip 5 and an electrode of the protective diode 3. A bottom surface of the lower lead frame body 133 is mounted on the PCB 9. The lower lead terminal 131 is electrically connected to external components through a wire.

The lower lead terminal 131 comprises a lower connection portion 1311 and a lower extending part 1313. The lower connection portion 1311 is used to connect the lower lead frame body 133 to the lower extending part 1313. A first end of the lower connection portion 1311 is connected to one end of the lower lead frame body 133. The lower connection portion 1311 extends obliquely from the lower lead frame body 133. The lower extending part 1313 is used as a solder point for electrically connecting to an external circuit through a wire. The lower extending part 1313 is connected to a second end of the lower connection portion 1311, and is substantially parallel to the lower lead frame body 133.

The upper lead frame 11 comprises an upper lead frame body 115 and an upper lead terminal 111. A light inlet window 113 is defined in the upper lead frame body 115. External light easily passes through the light inlet window 113 and strikes the photovoltaic chip 5, which is mounted between the upper lead frame 11 and the lower lead frame 13. The upper lead frame body 115 connects an electrode of the photovoltaic chip 5 and an electrode of the protective diode 3 in series. The upper lead terminal 111 is connected to external components by a wire.

The upper lead terminal 111 comprises an upper connection portion 1111 and an upper extending part 1113. The upper connection portion 1111 connects the upper lead frame body 115 to the upper extending part 1113. A first end of the upper connection portion 1111 is connected to one end of the upper lead frame body 115. The upper connection portion 1111 extends obliquely from the upper lead frame body 115. The upper extending part 1113 is used as a solder point for electrically connecting to an external circuit. The upper extending part 1113 is connected to a second end of the upper connection portion 1111, and is substantially parallel to the upper lead frame body 115.

In assembly, the photovoltaic chip 5 and the protective diode 3 are arranged side by side between the upper lead frame 11 and the lower lead frame 13, with the photovoltaic chip 5 and the protective diode 3 being spaced from each other. The photovoltaic chip 5 and the protective diode 3 are mounted on and are electrically connected to the top surface of the lower lead frame body 133 by joining material 7. The upper lead frame body 115 is mounted on and is electrically connected to top surfaces of the photovoltaic chip 5 and the protective diode 3 by the joining material 7, such that the light inlet window 113 is located directly above the photovoltaic chip 5. That is, the photovoltaic chip 5 faces toward the light inlet window 113. Thereby, the photovoltaic chip 5 and the protective diode 3 are assembled in series by the lower lead frame 13 and the upper lead frame 11. As a result, in use of the concentrating photovoltaic chip assembly 100, the photovoltaic chip 5 outputs electric energy via the upper lead terminal 111, and the lower lead terminal 131 is electrically connected to an external circuit.

In the embodiment, the joining material 7 is solder. In other embodiments, the joining material 7 is conductive adhesive.

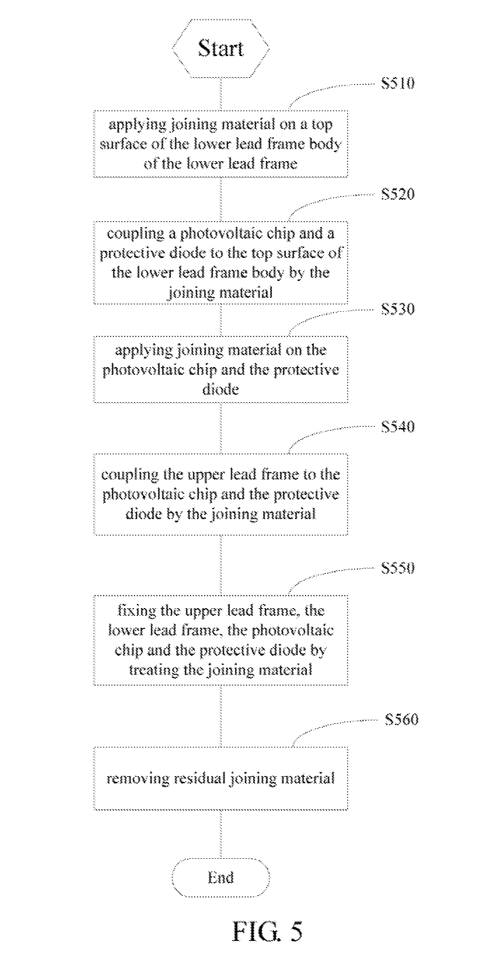

Referring to FIG. 5, an exemplary method for manufacturing the concentrating photovoltaic chip assembly 100 comprises the following steps:

In step S510, joining material 7 is applied on a top surface of the lower lead frame body 133 of the lower lead frame 13.

In step S520, the photovoltaic chip 5 and the protective diode 3 are coupled to the top surface of the lower lead frame body 133 by the joining material 7.

In step S530, joining material 7 is applied on the photovoltaic chip 5 and the protective diode 3.

In step S540, the upper lead frame 11 is coupled to the photovoltaic chip 5 and the protective diode 3 by the joining material 7, such that the light inlet window 113 is located directly above the photovoltaic chip 5. Accordingly, external light can pass through the light inlet window 113 and strike a surface of the photovoltaic chip 5.

In step S550, the upper lead frame 11, the lower lead frame 13, the photovoltaic chip 5, and the protective diode 3 are fixed (bonded) together by treating the joining material 7. In the embodiment, when solder is used as the joining material 7, the process of fixing the upper lead frame 11, the lower lead frame 13, the photovoltaic chip 5, and the protective diode 3 together is performed by reflow soldering. When conductive adhesive is used as the joining material 7, the process of fixing the upper lead frame 11, the lower lead frame 13, the photovoltaic chip 5, and the protective diode 3 together is performed by curing the conductive adhesive.

In step S560, any residual joining material 7 is removed.

In summary, in the embodiment, the lower lead frame body 133 supports the photovoltaic chip 5 and the protective diode 3. The photovoltaic chip 5 and the protective diode 3 are assembled in series by the lower lead frame body 133 and the upper lead frame body 115. The lower lead terminal 131 and the upper lead terminal 111 are electrically connected to the external circuit. Therefore the structure described above not only saves on the costs of gold wires and direct bonded copper, but also reduces the time required for mass production.

Although the features and elements of the present embodiments are described in particular combinations, each feature or element can be used alone or in other various combinations within the principles of the present embodiments to the full extent indicated by the broad general meaning of the terms in which the appended claims are expressed.

What is claimed is:

1. A concentrating photovoltaic chip assembly, comprising:
an upper lead frame defining a light inlet window;
a lower lead frame for supporting electronic components;
a photovoltaic chip for converting solar energy into electric energy; and
a protective diode for protecting the photovoltaic chip from short-circuiting;
wherein each of the photovoltaic chip and the protective diode is mounted between and electrically connected with the upper lead frame and the lower lead frame, and the photovoltaic chip faces toward the light inlet window.

2. The concentrating photovoltaic chip assembly of claim 1, wherein the upper lead frame comprise an upper lead frame body and an upper lead terminal, the light inlet window is defined in the upper lead frame body, and the upper lead terminal connects with the upper lead frame body and is used as a solder point for electrically connecting with an external circuit.

3. The concentrating photovoltaic chip assembly of claim 1, wherein the lower lead frame comprises a lower lead frame body and a lower lead terminal, and the lower lead terminal connects with the lower lead frame body and is used as a solder point for electrically connecting with an external circuit.

4. The concentrating photovoltaic chip assembly of claim 1, wherein the upper lead terminal comprises an upper extending part and an upper connection portion, the upper connection portion connects between the upper lead frame body and the upper extending part, the upper connection portion extends obliquely upwardly from an end of the upper lead frame body in a direction away from the upper lead frame body, and the upper extending part extends from the upper connection portion in a direction away from the upper lead frame body and is parallel with the upper lead frame body.

5. The concentrating photovoltaic chip assembly of claim 1, wherein the lower lead terminal comprises a lower extending part and a lower connection portion, the lower connection portion connects between the lower lead frame body and the lower extending part, the lower connection portion extends obliquely upwardly from an end of the lower lead frame body in a direction away from the lower lead frame body, and the lower extending part extends from the lower connection portion in a direction away from the lower lead frame body and is parallel with the lower lead frame body.

6. The concentrating photovoltaic chip assembly of claim 1, wherein the upper lead frame and the lower lead frame are electrically connected with the photovoltaic chip and the protective diode by one of conductive adhesive and solder.

7. A method for manufacturing a concentrating photovoltaic chip assembly, the method comprising:
applying joining material on a top surface of a lower lead frame;
coupling a photovoltaic chip and a protective diode to the lower lead frame by the joining material;
applying joining material on the photovoltaic chip and the protective diode;
coupling an upper lead frame to the photovoltaic chip and the protective diode by the joining material, with a light inlet window defined in the upper lead frame corresponding to the photovoltaic chip; and
fixing the upper lead frame, the lower lead frame, the photovoltaic chip and the protective diode together by treating the joining material.

8. The method of claim 7, further comprising removing any residual joining material.

9. The method of claim 7, wherein the joining material is solder.

10. The method of claim 9, wherein treating the joining material comprises reflow soldering.

11. The method of claim 7, wherein the joining material is conductive adhesive.

12. The method of claim 11, wherein treating the joining material comprises curing the conductive adhesive.

13. A concentrating photovoltaic assembly, comprising:
an optical element configured for concentrating light on a specific area;
a concentrating photovoltaic chip assembly, which comprises an upper lead frame defining a light inlet window, a lower lead frame for supporting electronic components, a photovoltaic chip for converting solar energy into electric energy, and a protective diode for protecting the photovoltaic chip from short-circuiting;
wherein each of the photovoltaic chip and the protective diode is mounted between and electrically connected with the upper lead frame and the lower lead frame, and the photovoltaic chip faces toward the light inlet window; and
wherein the optical element is positioned over the concentrating photovoltaic chip assembly corresponding to the light inlet window, and the optical element concentrates the light on the photovoltaic chip via the light inlet window.

14. The concentrating photovoltaic assembly of claim 13, wherein the optical element comprises a convex lens.

15. The concentrating photovoltaic assembly of claim 13, wherein the upper lead frame comprise an upper lead frame body and an upper lead terminal, the light inlet window is defined in the upper lead frame body, and the upper lead terminal connects with the upper lead frame body and is used as a solder point for electrically connecting with an external circuit.

16. The concentrating photovoltaic assembly of claim 13, wherein the lower lead frame comprises a lower lead frame body and a lower lead terminal, and the lower lead terminal connects with the lower lead frame body and is used as a solder point for electrically connecting with an external circuit.

17. The concentrating photovoltaic assembly of claim 13, wherein the upper lead terminal comprises an upper extending part and an upper connection portion, the upper connection portion connects between the upper lead frame body and the upper extending part, the upper connection portion extends obliquely upwardly from an end of the upper lead frame body in a direction away from the upper lead frame body, and the upper extending part extends from the upper connection portion in a direction away from the upper lead frame body and is parallel with the upper lead frame body.

18. The concentrating photovoltaic assembly of claim 13, wherein the lower lead terminal comprises a lower extending part and a lower connection portion, the lower connection portion connects between the lower lead frame body and the lower extending part, the lower connection portion extends obliquely upwardly from an end of the lower lead frame body in a direction away from the lower lead frame body, and the lower extending part extends from the lower connection portion in a direction away from the lower lead frame body and is parallel with the lower lead frame body.

19. The concentrating photovoltaic assembly of claim 13, wherein the upper lead frame and the lower lead frame are electrically connected with the photovoltaic chip and the protective diode by one of conductive adhesive and solder.
